(19) United States
(12) Patent Application Publication
(10) Pub. No.: US 2011/0186121 A1
(43) Pub. Date: Aug. 4, 2011

(54) METAL-CONTAINING COMPOSITION, METHOD FOR PRODUCING ELECTRICAL CONTACT STRUCTURES ON ELECTRICAL COMPONENTS AND ALSO ELECTRICAL COMPONENT

(75) Inventors: Matthias Horteis, Freiburg (DE); Robert Woehl, Freiburg (DE); Stefan Glunz, Freiburg (DE); Aleksander Filipovic, Freiburg (DE); Daniel Schmidt, Freiburg (DE)

(73) Assignee: Fraunhofer-Gesellschaft Zur Forderung Der Angewandten Forschung E.V., Munchen (DE)

(21) Appl. No.: 13/003,252

(22) PCT Filed: Jul. 6, 2009
(86) PCT No.: PCT/EP2009/004877

§ 371 Date: Apr. 11, 2011

(30) Foreign Application Priority Data
Jul. 10, 2008 (DE) 10 2008 032 554.6

(51) Int. Cl. H01L 31/0224; H01B 1/22; H01B 1/14; H01L 31/18

(52) U.S. Cl. 136/256; 252/512; 252/519.21; 438/98; 257/E31.001

(57) ABSTRACT

The present invention relates to a metal-containing composition, a method for producing electrical contact structures on electronic components and also an electronic component provided with such a contacting.

The present invention relates to a metal-containing composition, a method for producing electrical contact structures on electronic components and also an electronic component provided with such a contacting.

Silicon solar cells normally have metallic contacts both on the front-side and on the rear-side. Precisely the contacts on the front-side have several tasks to fulfil and therefore place high demands on the contacting method and also on the contact material system. The front-side contacts must both

produce the electrical contact to the semiconductor, ensuring that the current can be transported away with as little loss as possible,

have a sufficiently good mechanical adhesion,

and be, for their part, contactable in turn, e.g. for cell connectors, in the wiring to a module.

The combination of all these tasks in one material system means making compromises and either dispensing with a good electrical contact in favour of the conductivity or accepting losses in the electrical conductivity in order to achieve a good electrical metal-semiconductor junction. The contacts on the front-side always become narrower in the process of optimising the solar cell with respect to improved efficiency. This has the result that the shading is minimised, this in turn causes a greater current which, in order to transport it from the cell with low loss, requires high conductivity in the contact fingers. The material systems available at present can in fact be printed on the solar cell with the corresponding technology in thin strip conductors, which means low shading of the cell, however these are not optimised with respect to the electrical contact resistance and the mechanical adhesion so that the gain on the basis of the low shading is overcompensated for by losses in the contact resistance. Furthermore, the mechanical adhesion, with a contact width of <50 μm, is frequently no longer provided. In the case of solar cells which have a high-resistance emitter (>70 ohm/square), contact formation with the existing material systems is possible only with difficulty.

In order to circumvent the problem of achieving all the requirements, such as high electrical conductivity, a good electrical contact, high mechanical adhesion and good solderability in one material system or in one printing step, the possibility exists of two-stage contacting (WO 2007/085448). A thin layer, so-called seed layer, is thereby applied in a first printing step, which layer is responsible in particular for the electrical contact and for the mechanical adhesion. This layer can be produced for example by inkjet printing, aerosol printing, tampon printing or fine line screen printing. In a further process step, a metal layer which is optimised to have very good electrical conductivity and, for its part, to be readily contactable is applied.

The actual contact, after the ink/paste has been applied, is formed in a temperature step, contact firing. At a temperature of approx. 500° C., the glass frit thereby melts and wets the antireflective layer, at temperatures around 750° C. the glass melt in which at this temperature also silver is dissolved penetrates the antireflective layer and penetrates further into the silicon, the dissolved silver is separated from the melt during cooling and crystallises directly on the silicon surface in the form of small silver crystallites. The cooled glass forms an insulating barrier between the volume silver of the finger and the silver crystallites which is sufficiently thin at some points so that a current can flow out of the cell into the contacts.

This second metal layer can be produced for example by galvanic reinforcement of the first layer or by printing on further, particularly readily conductive metal layers onto the first contact layer.

With all mentioned printing systems, line widths below 50 μm are achievable, however a good electrical contact has to date only been able to be achieved with vacuum-deposited metal contacts. This technology is known from microelectronics but is too cost-intensive for use in the PV industry. For direct printing of metal inks/pastes for applying the seed layer and contacting the solar cell, there exists to date no special paste/ink. Those which are used correspond, in composition, to a screen printing front-side paste. Such a paste/ink consists up to approx. 60 to 80% by weight of a readily conducting metal, e.g. silver, up to approx. 2 to 5% by weight of a glass frit and up to 20 to 40% by weight of an organic vehicle system via which the rheology of the ink/paste is substantially adjusted. The contacts, as long as these are produced in a single printing step, e.g. screen printing, typically have an application height of approx. 15 μm and a width of 120 μm. This means that, in this case, a substantially greater contact surface is available and therefore the requirements placed upon the contact properties of the paste can be less. In addition, it is known that the specific contact properties are impaired with reduced metal layer height.

Compositions for producing contacts by firing are known from various literature references, e.g. U.S. Pat. No. 6,036,889, US 2004/0151893, US 2006/0102228, U.S. Pat. No. 4,153,907 and also U.S. Pat. No. 6,814,795. Increased contact resistance is common to all known formulations as soon as thin contact structures on low-doped emitters are used.

In order to achieve an increase in efficiency by solar cells, it is particularly important to develop a contact ink/paste with which it is possible to produce thin contacts on high-resistance emitters having low junction resistance between metal and semiconductor (metal contact and solar cell).

Hence, it was the object of the present invention to provide a composition with which as low-resistance junction resistances as possible between metal and semiconductor can be achieved with, at the same time, thin contacts which in addition have strong mechanical adhesion to the substrate. Likewise, it was the object of the present invention to indicate a method for producing electrical contact structures on electronic components and also to indicate the electronic components which can be produced according to the invention.

This object is achieved, with respect to the metal-containing composition, by the features of patent claim 1, with respect to the method for producing an electronic contact structure, by the features of patent claim 13 and also, with respect to the electronic component, by the features of patent claim 18. The respective dependent claims thereby represent advantageous developments.

In order to improve the electrical contact with thin line widths (<50 μm) and above all low application heights <2 μm, material systems are provided according to the invention which in particular improve the junction resistance of the metal to the semiconductor and, at the same time, have high adhesion. The compositions according to the invention comprise:

a) in a quantity of 20 to 80% by weight relative to 100% by weight of the composition, at least one electrically conductive metal powder and/or a powder of a metallic alloy and/or at least one metallo-organic compound of the conductive metal,

b) at least a first oxidic material, selected from the group consisting of glasses, ceramics, metal oxides with a melting point below 1,000° C. and/or metallo-organic compounds derived from metals contained in the previously mentioned glasses, ceramics and/or metal oxides and/or mixtures hereof, and also

c) at least a second oxidic material, selected from the group consisting of ceramics and/or metal oxides with a melting point of at least 1,100° C. and/or metallo-organic compounds derived from metals contained in the previously mentioned ceramics and/or metal oxides and/or mixtures hereof.

The composition according to the invention concerns for example a combination of silver and glass or low-melting oxide and a “pure” high-melting oxide, hence a combination of silver and oxides, the oxide proportion being comparatively high and the silver proportion comparatively low. The source for oxides and silver can thereby be MOD (metallo-organic decomposition materials) which are also known in the expert field.

It is hereby particularly advantageous that a material system with a reduced silver proportion also implies a cost reduction in production. Furthermore, it is possible for the first time with the present invention to contact solar cells with a high-resistance emitter and hence a high efficiency potential, with narrow, low-resistance contacts. To date, contact widths of at least 80 μm have been required to contact emitters with a layer resistance >100 ohm/square in a low-resistance manner, ρ_{c}<10 mohmcm². With the composition according to the invention, emitters>100 ohm/square can be contacted with contacts<20 μm with a specific contact resistance ρ_{c}<2 mohmcm². Hence it is possible for the first time to contact solar cells with a high efficiency potential at reduced costs, e.g. currently 20.3% with a layer resistance of 110Ω/square on a 2×2 cm² cell could be achieved.

According to the invention, there is contained in addition at least one organic component d) in the composition, selected from the group consisting of
aa) solvents, preferably solvent with a boiling point>100° C.; in particular solvents selected from the group consisting of terpineol, ethylene glycol ether, glycol ether, diethylene glycol monobutyl ether, N-methylpyrrolidone, ethylene glycol and/or mixtures hereof,
bb) binders, in particular ethyl cellulose and/or
cc) dispersants, selected from the group consisting of hydroxy-functional carboxylic acid esters with pigment-affine groups, copolymers with acidic groups, alkylol ammonium salts of a block copolymer with acidic groups and/or mixtures or solutions hereof.

Furthermore, it is advantageous if the electrically conductive metal according to feature a) of patent claim 1 is selected from the group consisting of metals with an electrical conductivity of at least 40·10⁶ S/m, preferably at least 55·10⁶ S/m, in particular is silver, and/or the at least one metallo-organic compound of the conductive metal is selected from the group consisting of metallo-organic decomposition materials (MOD), preferably of metal salts of fatty acids, in particular metal resinates, particularly preferred of silver resinate, silver neodecanoate and/or silver (hexafluoroacetylacetonate) (1,5-cyclooctadiene) and also mixtures hereof.

The first oxidic material b) is preferably selected from the group consisting of glass frits, preferably lead glass- and/or bismuth glass frits; lead-II-oxide; bismuth trioxide and/or the metallo-organic compounds derived from the contained metals of the first oxidic compound are selected from the group consisting of metallo-organic decomposition materials (MOD), preferably of metal salts of fatty acids, in particular metal resinates, particularly preferred of bismuth resinate, bismuth neodecanoate, bismuth-2-ethylhexanoate and also mixtures hereof.

It is likewise preferred if the second oxidic material c) is selected from the group consisting of ZnO, ZnO:Al, SnO, TiO, TiO₂, MgO and/or the metallo-organic compounds derived from the contained metals of the second oxidic compound are selected from the group consisting of metallo-organic decomposition materials (MOD), preferably of metal salts of fatty acids, in particular metal resinates, particularly preferred of zinc resinate and/or zinc neodecanoate and also mixtures hereof.

Hence also metallo-organic compounds or metal salts, which are known in general under the specialist term metallo-organic decompositions (MOD), serve as source for the previously mentioned oxides or conductive metals. Metal salts of fatty acids, also often termed resinates, such as silver neodecanoate, Ag (hfa) (COD), bismuth-2-ethylhexanoate, bismuth neodecanoate, zinc neodecanoate, are particularly suitable.

The combination with a further resinate which burns to form a metal oxide which has a melting point above 1,000° C., such as zinc resinates, e.g. zinc neodecanoates, is hereby particularly advantageous.

Precisely the addition of zinc oxide as oxide powder or as zinc resinate increases the formation of silver crystallites which are responsible for the electrical contact in the contact formation on solar cells.

The crystal density, a measure of the contact quality, is significantly increased in the presence of ZnO in the contact material system.

This need not thereby explicitly concern a glass system, which is a further substantial difference from previous publications. Oxides have to date always been mixed in the form of glass with the contact metal.

The possibility is likewise given that the low- or high-melting oxides a) or b) can be present as glass, i.e. as oxide mixture or as respectively fine oxide as coating around a silver particle.

Mixtures of resinates and powders in all combinations are conceivable. The combination of silver powder with resinates (bismuth resinate, zinc resinate) for producing a contact ink or paste is particularly promising.

With respect to the quantity proportions to respectively 100% by weight of the composition, with respect to the individual components a) to d) independently of each other, the respective range data subsequently indicated are preferred:

component a): in a quantity of 25 to 75% by weight, preferably of 30 to 70% by weight, particularly preferred 30 to 68% by weight;

component b): in a quantity of 0.1 to 20% by weight, preferably between 1 and 10% by weight, particularly preferred between 1.5 and 7.5% by weight;

component c): in a quantity of 1 to 80% by weight, preferably between 3 and 70% by weight;

component d): in a quantity of 0 to 50% by weight, preferably between 10 and 40% by weight, particularly preferred between 20 and 30% by weight.

The composition according to the invention can be present in various ready-to-use formulations. As a preferred embodiment, the composition is designed in the form of an inkjet ink or aerosol ink which is distinguished by a viscosity η<1,000 mPas, preferably η<100 mPas. Likewise, it is however possible and advantageous if the composition is designed in the form of a paste which is to be applied for example by screen printing, the paste being distinguished by a viscosity 10 Pas<η<300 Pas. The viscosities can thereby be varied or adjusted for example by the addition of a suitable organic material d) according to general principles known to the person skilled in the art, e.g. with respect to the choice of material or the quantity thereof or a mixture of materials, and hence can be coordinated to the respective purpose of use.

Independently of the consistency of the composition and independently of the particles used, the at least one electrically conductive metal a), the at least one oxidic material b) and/or the at least one oxidic material c), likewise respectively independently of each other, are present as particles or powders, the average particle sizes d₅₀, respectively independently of each other, being between 1 nm and 10 μm.

The printing techniques must also be differentiated here from each other, for example in the case of inkjet inks, a d₅₀<200 nm is necessary, preferably <100 nm, whilst, with aerosol applications, a d₅₀<1 μm is particularly suitable and, with screen printing, particularly fine line screen printing, a d₅₀<10 μm, particularly preferred d₅₀5 μm.

In an alternative preferred embodiment, the composition according to the invention is free of particles. This is the case in particular when the components a) to c) comprise merely the above-mentioned MODs (metallo-organic decomposition materials). This embodiment is suitable in particular for low-viscous compositions and offers particular advantages if very fine, i.e. narrow, contact structures are intended to be produced structurally.

Of course, it is likewise advantageous if the compositions according to the invention comprise both particle-free and particle-containing components a) to c) in combination with each other.

According to the invention, a method for producing an electrical contact structure on an electronic component is likewise indicated, in which
a) a composition as described previously is applied on the electronic component in a form reproducing the contact structure to be produced and
b) the component provided with the composition is heated in a contact firing step to a temperature between 400 and 900° C.

According to the invention, it is hence provided that the composition is applied on the component already in a form reproducing the ultimate contact structure, i.e. for example in the form of strip conductors. It is however likewise possible that, if the preparation is intended to be effected in larger conductive surfaces, a corresponding planar application of the composition is possible. The application is thereby effected preferably already in the proportions with respect to length, width and height in the form of the subsequently desired dimension of the conductor structure. Due to the property of the composition according to the invention, good adhesion of the composition to the component is possible so that it is ensured that as narrow as possible and yet mechanically very stable strip conductors can be produced; likewise it is ensured by the type of composition that an optimal connection of the produced conductive structure to the component is ensured after the concluding heating step.

Preferably, the composition according to the invention is applied by screen printing, aerosol printing, inkjet printing, tampon printing, template printing, dispensing and/or combinations hereof.

Advantageous temperature ranges of the heating step b) are between 700 and 850° C.

It is likewise preferred if an application is effected in the form of strip conductors with a width of <50 μm, preferably <40 μm, particularly preferred <35 μm.

According to the invention, an electronic component, in particular solar cell, with an electrical contact structure is likewise provided, the electronic component having an electrical contact structure which can be produced according to the method according to the invention.

The invention is explained in more detail with reference to the subsequent embodiments and examples and also the enclosed Figure without restricting the invention to the special parameters subsequently indicated.

The compositions provided according to the invention, in particular pastes/inks are composed of
a conductive metal, above all silver,
a glass system, preferably lead glass or bismuth glass, which can be replaced also by a readily wetting metal oxide, lead oxide (PbO) or bismuth oxide (Bi₂O₃).

In addition to the metal and the glass frit/wetting oxide, a further metal oxide with a melting point far above the contact firing temperature of approx. 750° C. is used. There may be mentioned as examples: ZnO (melting point mp. 1,800° C.), ZnO:Al (mp. 1,800° C.), SnO (mp. 1,127° C.), TiO₂ (mp. 1,830° C.), MgO (mp. 2,800° C.), preferably ZnO, ZnO:Al and also CaO.

The use of one of these oxides or in combination does in fact reduce the electrical conductivity of the contacts but these oxides substantially improve both the mechanical stability and the electrical metal-semiconductor junction. In combination with a wetting oxide or glass frit and the contact material, silver, such a material system is very well suited as seed layer.

The high melting point has the effect that the oxides do not melt completely during contact firing but are present in the contact structure as solid particles and contribute to the layers “meshing” better to each other and hence the adhesion is increased. Furthermore, it is conceivable that the gases being released during the contact firing (N₂, H₂ from the front-side antireflection layer (SiNₓ layer) or organic combustion products, H₂O and CO₂ from the printed contact ink) can escape better from the contact and therefore the contact structure is more compact and less porous. Both have a positive effect on the mechanical adhesion and on the electrical contact.

Furthermore, the electrical contact is substantially improved above all when using ZnO or ZnO:Al. Both ZnO, heated to above 430° C., and the zinc oxide doped with aluminium have high electrical conductivity, which leads to the fact that the current can flow better through the glass layer. A further conceivable current path extends from the silver crystallite via a conductive oxide particle to the contact silver. Because of the property that ZnO is an n-type semiconductor, it is possible also to contact high-resistance emitters (>70 ohm/square) with a contact ink/paste which contains this oxide, in a low-resistance manner. The oxides used, in particular ZnO, also promote the growth of the silver crystallites and hence the density thereof which are crucial for the contact formation. Hence, for the first time pastes or inks with substantially better contact properties are produced and tested on silicon solar cells. With very thin contact lines (30 μm), very good electrical parameters on solar cells with high-resistance emitters (contact resistance, filling factor and efficiency of the cells) could be achieved.

The newly developed printing ink can be applied on the solar cell as seed layer, e.g. in the aerosol printing method, inkjet method, in the fine line screen printing method or in the tampon printing method.

According to which printing method is used, it is necessary to adapt the rheology of the paste/ink. In the case of a fine line screen printing paste, the viscosity is at η>1 Pas, with an aerosol ink the viscosity should be <1 Pas and with an inkjet ink it is necessary to reduce the viscosity to <100 mPas. Since with these contact pastes/inks good electrical and mechanical contact is primarily important, the proportion of an additional metal oxide, e.g. ZnO, can be varied greatly and varied in a range of 3% by weight up to 70% by weight. The higher the metal oxide proportion, the more low-resistance is the metal-semiconductor junction and all the smaller is the electrical transverse conductivity of the contact. The proportion of the wetting glass frit, lead glass frit or bismuth glass frit or the metal wetting oxides, PbO, Bi₂O₃ can be varied between 1% by weight and 10% by weight, the proportion is preferably at 2 to 3% by weight. To the same degree as the metal oxide proportion varies, the proportion of conductive metal (silver) is changed and moves between 30% by weight and 70% by weight.

### EMBODIMENTS

### Example 1

Seed layer ink/paste with high silver content and lead glass frit:

60% by weight of silver,

2% by weight of lead glass frit,

10% by weight of ZnO,

28% by weight of N-methylpyrrolidone, diethylene glycol monobutyl ether, Disperbyk 180/182,

### Example 2

Seed layer ink/paste with a high silver content and bismuth glass fit:

60% by weight of silver,

2% by weight of bismuth glass frit,

10% by weight of ZnO,

28% by weight of N-methylpyrrolidone, diethylene glycol monobutyl ether, Disperbyk 180/182

### Example 3

Seed layer ink/paste with high oxide proportion:

35% by weight of silver,

2% by weight of lead glass frit,

35% by weight of ZnO,

28% by weight of N-methylpyrrolidone, diethylene glycol monobutyl ether, Disperbyk 180/182,

### Example 4

Seed layer ink/paste without lead glass fit, instead with wetting oxide:

60% by weight of silver (Ag),

5% by weight of bismuth oxide (Bi₂O₃),

10% by weight of zinc oxide (ZnO),

28% by weight of N-methylpyrrolidone, diethylene glycol monobutyl ether, Disperbyk 180/182,

### Example 5

Seed layer ink paste in which the oxides are present as resinates and only silver is present in particle form:

60% by weight of silver (Ag),

10% by weight of zinc resinate (zinc neodecanoates),

5% by weight of bismuth resinate (bismuth neodecanoates),

25% by weight of N-methylpyrrolidone, diethylene glycol butyl ether, Disperbyk 182, xylene,

### Example 6

Seed layer ink/paste—particle free:

40% by weight of silver resinate,

10% by weight of zinc resinate,

5% by weight of bismuth resinate,

45% by weight of xylene, NMP, toluene.

By using conductive, high-melting oxides, such as zinc oxide, in combination with a readily wetting, low-melting oxide, such as bismuth oxide, or a readily wetting glass frit, such as lead glass frit or bismuth glass frit, it is possible to contact high-resistance emitters (Rₛₕ>70 ohm/square) and to achieve good adhesion at the same time. The proportion of zinc oxide can thereby be increased up to 35% by weight, the proportion of silver being greatly reduced.

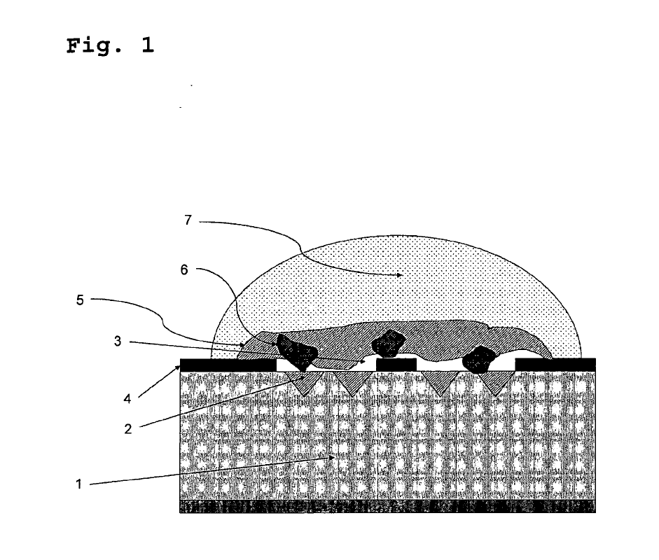

The construction of an electronic component which can be produced by the method according to the invention using the composition according to the invention, as in the present case of a coated solar cell, is represented in FIG. 1.

In FIG. 1, a semiconductor component 1, e.g. made of silicon, is represented. On the surface orientated towards the metallisation, silver crystallites 2 are disposed. In these regions of the surface, a glass layer 3 is deposited and interrupted by an antireflection layer 4 in the silver crystallite-free regions. On the surface, conductive oxide particles 6 are represented in addition, which can be embedded both in the silver layer 5 and the glass layer 3. Finally, a conductive metal layer 7, e.g. made of silver or copper, is applied.

1. Metal-containing composition for producing a contact structure on an electronic component, comprising
a) in a quantity of 20 to 80% by weight relative to 100% by weight of the composition, at least one electrically conductive metal powder and/or a powder of a metallic alloy and/or at least one metallo-organic compound of the conductive metal,
b) at least a first oxidic material, selected from the group consisting of glasses, ceramics, metal oxides with a melting point below 1,000° C. and/or metallo-organic compounds derived from metals contained in the previously mentioned glasses, ceramics and/or metal oxides and/or mixtures thereof, and also
c) at least a second oxidic material, selected from the group consisting of ceramics and/or metal oxides with a melting point of at least 1,100° C. and/or metallo-organic compounds derived from metals contained in the previously mentioned ceramics and/or metal oxides and/or mixtures thereof, and also
d) at least one organic component selected from the group consisting of
aa) solvents, preferably solvent with a boiling point>100° C.; in particular solvents selected from the group consisting of terpineol, ethylene glycol ether, glycol ether, diethylene glycol monobutyl ether, N-methylpyrrolidone and/or mixtures thereof,
bb) binders, in particular ethyl cellulose and/or
cc) dispersants, selected from the group consisting of hydroxy-functional carboxylic acid esters with pigment-affine groups, copolymers with acidic groups, alkylol ammonium salts of a block copolymer with acidic groups and/or mixtures or solutions thereof.

2. The composition according to claim 1, wherein
the electrically conductive metal is selected from the group consisting of metals with an electrical conductivity of at least 40·10⁶ S/m, preferably at least 55·10⁶ S/m, in particular is silver, and/or the at least one metallo-organic compound of the conductive metal is selected from the group consisting of metallo-organic decomposition materials (MOD), preferably of metal salts of fatty acids, in particular metal resinates, particularly preferred of silver resinate, silver neodecanoate and/or silver (hexafluoroacetyl acetonate) (1,5-cyclooctadiene) and also mixtures thereof.

3. The composition according to claim 1, wherein the first oxidic material b) is selected from the group consisting of glass frits, preferably lead glass- and/or bismuth glass frits; lead-II-oxide; bismuth trioxide and/or the metallo-organic compounds derived from the contained metals of the first oxidic compound are selected from the group consisting of metallo-organic decomposition materials (MOD).

4. The composition according to claim 1, wherein the second oxidic material c) is selected from the group consisting of ZnO, ZnO:Al, SnO, TiO, TiO₂, CaO, MgO and/or the metallo-organic compounds derived from the contained metals of the second oxidic compound are selected from the group consisting of metallo-organic decomposition materials (MOD),

5. The composition according to claim 1, wherein, relative to 100% by weight of the composition, the at least one component a) is comprised in a quantity of 25 to 75% by weight.

6. The composition according to claim 1, wherein, relative to 100% by weight of the composition, the at least one component b) is comprised in a quantity of 0.1 to 20% by weight.

7. The composition according to claim 1, wherein, relative to 100% by weight of the composition, the at least one component c) is comprised in a quantity of 1 to 80% by weight.

8. The composition according to claim 1, wherein, relative to 100% of the composition, the at least one organic component d) is comprised in a quantity of 0 to 50% by weight.

9. The composition according to claim 1, in the form of an inkjet ink or aerosol ink, having a viscosity η<1,000 mPas.

10. The composition according to claim 1, in the form of a screen printing paste, having a viscosity 10 Pas<η<300 Pas.

11. The composition according to claim 1, wherein the at least one electrically conductive metal a), the at least one oxidic material b) and/or the at least one oxidic material c) are comprised as particles, the average particle sizes d₅₀, respectively independently of each other, being between 1 nm and 10 μm.

12. The composition according to claim 1, wherein the composition is free of particles.

13. A method for producing an electrical contact structure on an electronic component comprising
aa) applying a composition according to claim 1 on the electronic component in a form reproducing the contact structure to be produced and
bb) heating the component provided with the composition in a contact firing step to a temperature between 400 and 900° C.

14. The method according to claim 13, wherein the application of the composition is effected by screen printing, aerosol printing, inkjet printing, tampon printing, template printing, dispensing and/or combinations thereof.

15. The method according to claim 13, wherein the component is heated in step b) to a temperature between 700 and 850° C.

16. The method according to claim 13, wherein the application is effected in the form of strip conductors with a width of <50 μm.

17. An electronic component having an electrical contact structure prepared in accordance with claim 13.

18. The composition according to claim 3, wherein the metallo-organic decomposition materials (MOD) are selected from the group consisting of bismuth resinate, bismuth neodecanoate, bismuth-2-ethylhexanoate and also mixtures thereof

19. The composition according to claim 4, where the metallo-organic decomposition materials (MOD) are selected from the group consisting of zinc resinate and/or zinc neodecanoate and mixtures thereof

20. The composition according to claim 5, wherein the at least one component a) is comprised in a quantity of 10 to 68% by weight.

21. The composition according to claim 6, wherein the at least one component b) is comprised in a quantity of 1.5 to 7.5% by weight.

22. The composition according to claim 8, wherein the at least one organic component d) is comprised in a quantity of 20 to 30% by weight.

23. The composition according to claim 9, wherein the inkjet or aerosol ink has a viscosity of η<100 mPas.

24. The method of claim 16, wherein the strip conductors have a width of <35 μm.

25. The electronic component of claim 17, wherein the component is a solar cell.
